(19) United States
(12) Patent Application Publication
(10) Pub. No.: US 2026/0269192 A1
(43) Pub. Date: Sep. 10, 2026

(54) EDGE RING FOR SEMICONDUCTOR MANUFACTURING APPARATUS AND MANUFACTURING METHOD THEREFOR

(71) Applicant: TOKAI CARBON KOREA CO., LTD., Gyeonggi-do (KR)

(72) Inventor: Jin Won SEO, Gyeonggi-do (KR)

(21) Appl. No.: 19/489,289

(22) PCT Filed: May 17, 2024
(86) PCT No.: PCT/KR2024/006700

§ 371 Date: Dec. 2, 2025

(30) Foreign Application Priority Data
Jun. 2, 2023 (KR) 10-2023-0071952

(51) Int. Cl. H01J 37/32; H01J 9/24; H10P 72/00

(52) U.S. Cl. CPC H01J 37/32642; H01J 9/24; H01J 37/32467; H10P 72/0421; H01J 2237/3341

(57) ABSTRACT

Disclosed herein are an edge ring for a semiconductor manufacturing apparatus and a manufacturing method therefor. The edge ring for a semiconductor manufacturing apparatus includes: an upper layer having high hardness; and a lower layer positioned below the upper layer and having lower hardness than the upper layer, where the lower layer may be positioned to be in contact with an internal component of a plasma etching apparatus.

### TECHNICAL FIELD

The present disclosure relates to an edge ring for a semiconductor manufacturing apparatus and a manufacturing method thereof.

### BACKGROUND ART

In order to ensure the uniformity of plasma irradiated on wafers for manufacturing wafer edge chips, the temperature uniformity of wafers and edge rings (or focus rings) must be secured. Thus, a smooth supply of He gas for cooling the edge rings and wafers is required.

A chemical vapor deposition (CVD) SiC material with high corrosion resistance for fine line width and multi-stage etching has excellent plasma resistance, but has poor adhesion to other components due to high hardness compared to silicon, and there are cases where leakage of He for cooling occurs, making product application impossible.

There is a hybrid method of attaching silicon to CVD SiC, where a lower portion that contacts with other components is made of silicon and bonded to an upper portion which is CVD SiC. However, there is a high possibility of particles being generated during the process due to the use of adhesives or the like, and the manufacturing process is complicated, which may result in high costs due to increased production costs. Also, the adhesive strength of the adhesive decreases at high temperatures and the CVD SiC portion and the silicon portion may be displaced, which may cause an upper CVD SiC portion to warp or separate during the process.

### DISCLOSURE OF THE INVENTION

### Technical Goals

In order to solve the aforementioned problems, the disclosure provides a component for a semiconductor manufacturing apparatus that has improved adhesion to other components and improved plasma resistance by applying high-hardness and low-hardness materials. For example, it is possible to improve the He leakage phenomenon that occurs when using a CVD SiC edge ring of the related art, and to provide an edge ring with improved adhesion to other components and improved plasma resistance when mounted on a semiconductor manufacturing apparatus.

The disclosure provides a method of manufacturing a component for a semiconductor manufacturing apparatus, which may manufacture a component for a semiconductor manufacturing apparatus by a simple method such as a continuous deposition (e.g., CVD) process or bonding using a method of adjusting a ratio of Si and C in raw materials supplied during a manufacturing process.

However, technical goals to be achieved are not limited to those described above, and other goals not mentioned above may be clearly understood by one of ordinary skill in the art from the following description.

### Technical Solutions

An edge ring according to an embodiment may include an upper layer having high hardness; and a lower layer positioned on a lower portion of the upper layer and having lower hardness than the upper layer, and the lower layer may be positioned to be in contact with an internal component of a plasma etching apparatus.

According to an embodiment, the upper layer may be formed of SiC or B₄C.

According to an embodiment, the upper layer may have a thickness of 1 millimeter (mm) or more.

According to an embodiment, the lower layer may be formed of C/SiC or C/B₄C.

According to an embodiment, the lower layer may be formed of a C/SiC material, and an atomic ratio of Si:C may be 1:1.4 to 1:1.6.

According to an embodiment, the lower layer may be formed of a C/B₄C material, and an atomic ratio of B:C may be more than 0:1 to less than 4:1.

According to an embodiment, the lower layer may have a Vicker's hardness of 1000 kg_{f}/mm² to 2000 kg_{f}/mm².

According to an embodiment, the lower layer may have a thickness of 0.2 mm or more.

According to an embodiment, the lower layer may be deposited and formed on the upper layer.

According to an embodiment, the edge ring may be deposited using a chemical vapor deposition (CVD) method, when the lower layer is formed of C/SiC, deposition may be performed while continuously changing a raw material ratio of Si to C, and when the lower layer is formed of C/B₄C, deposition may be performed while continuously changing a raw material ratio of B to C.

According to an embodiment, a method of manufacturing an edge ring may include forming a high-hardness upper layer, forming a lower layer having lower hardness than the upper layer, and processing in a component form.

According to an embodiment, when forming the upper layer, the upper layer may be formed by CVD, reaction sintering, or sintering.

According to an embodiment, when forming the lower layer, the lower layer may be deposited on the upper layer.

According to an embodiment, when forming the lower layer, the lower layer may be deposited while continuously changing a raw material ratio of B:C or Si:C.

According to an embodiment, when forming the lower layer, the upper layer and the lower layer may be bonded.

According to an embodiment, the bonding of the upper layer and the lower layer may be performed using at least one or more of an adhesive, heat, and pressure, or a combination thereof.

A method of reproducing a composite material component for a semiconductor manufacturing apparatus that is a method of reproducing the edge ring, may include forming a lower layer on a lower surface of an upper layer of a focus ring; and processing a shape of the focus ring to contain the lower layer.

According to an embodiment, the upper layer may include SiC or B₄C, and the lower layer may include C/SiC or C/B₄C.

According to an embodiment, the forming of the lower layer may include forming the lower layer on at least one of a lower surface, an upper surface, or a side surface of the focus ring, and the upper surface may be a plasma-exposed surface.

According to an embodiment, the processing of the shape of the focus ring may include processing the shape so that the C/SiC coating layer becomes a lower surface of the focus ring.

According to an embodiment, the processing of the shape of the focus ring may include processing the shape into a focus ring including an upper surface that has an area designed for wafer seating and is a plasma-exposed surface; and a lower surface.

According to an embodiment, the forming of a lower surface on at least one surface of the focus ring may include attaching a jig for coating on the at least one surface of the focus ring, the attaching of the jig for coating may be attaching the jig for coating on an upper surface of the focus ring and include depositing the lower surface on the at least one surface of the focus ring, to which the jig is attached, and the depositing of the lower layer may be depositing the lower layer on at least one surface except for the surface, on which the jig for coating is formed, and include removing the jig for coating after the depositing of the lower layer.

According to an embodiment, the method may include processing a shape of a lower surface and/or an upper surface of the focus ring.

### Effects of the Invention

According to an embodiment of the disclosure, the disclosure may provide a component (e.g., an edge ring) for a semiconductor manufacturing apparatus and a method of manufacturing the same, which may prevent damage with excellent resistance in a severe environment (e.g., a chemical usage environment of plasma, high temperature, high pressure, gas, etching, or the like) in a semiconductor manufacturing process, and may implement process stability by having excellent adhesion to other components (e.g., a ceramic component) and a semiconductor substrate (e.g., a wafer substrate) within a semiconductor manufacturing apparatus. According to an embodiment of the disclosure, the semiconductor manufacturing apparatus is an edge ring, and the disclosure may provide, for example, an edge ring that may increase adhesion to other ceramic components by applying a material having hardness similar to or lower than silicon (e.g., a C-rich material) (e.g., C/SiC or C/B₄C) to a portion where a He gas for cooling is injected and moves in a semiconductor plasma processing process, and may improve plasma resistance and solve the He gas leakage problem by forming a portion exposed to plasma with a high-hardness material (e.g., SiC or B₄C).

### BRIEF DESCRIPTION OF DRAWINGS

FIG. 1A illustrates a configuration of an edge ring in which an upper layer (e.g., a SiC layer or B₄C) and a lower layer (e.g., C/SiC or C/B₄C) are laminated according to an embodiment of the disclosure.

FIG. 1B illustrates a configuration of an edge ring in which an upper layer (e.g., a SiC layer or B₄C), an adhesive layer, a lower layer (e.g., C/SiC or C/B₄C) are laminated according to an embodiment of the disclosure.

FIG. 2 illustrates a change in Vicker's hardness of a C/SiC material according to a Si:C raw material ratio according to an embodiment of the disclosure.

FIG. 3A illustrates crystal characteristics (X-ray diffraction (XRD)) of a SiC material layer (Si:C raw material ratio=1:1 to 1.1) manufactured in examples of the disclosure according to an embodiment of the disclosure.

FIG. 3B illustrates crystal characteristics (XRD) of a C/SiC material (Si:C raw material ratio=1:1.2 to 1.4) manufactured in examples according to an embodiment of the disclosure.

FIG. 3C illustrates crystal characteristics (XRD) of a C/SiC material (Si:C raw material ratio=1:1.5 to 1.6) manufactured in examples according to an embodiment of the disclosure.

FIG. 4A illustrates a scanning electron microscope (SEM) image of a surface of a C/SiC material according to a Si:C raw material ratio (Si:C raw material ratio=1:1.1) according to an embodiment of the disclosure.

FIG. 4B illustrates an SEM image of a surface of a C/SiC material according to a Si:C raw material ratio (Si:C raw material ratio=1:1.2) according to an embodiment of the disclosure.

FIG. 4C illustrates an SEM image of a surface of a C/SiC material according to a Si:C raw material ratio (Si:C raw material ratio=1:1.3) according to an embodiment of the disclosure. 20 FIG. 4D illustrates an SEM image of a surface of a C/SiC material according to a Si:C raw material ratio (Si:C raw material ratio=1:1.4) according to an embodiment of the disclosure.

FIG. 4E illustrates an SEM image of a surface of a C/SiC material according to a Si:C raw material ratio (Si:C raw material ratio=1:1.5) according to an embodiment of the disclosure.

FIG. 4F illustrates an SEM image of a C/SiC material layer according to a Si:C raw material ratio (Si:C raw material ratio=1:1.6) of a composite material manufactured in Example 1.

FIG. 5A illustrates crystal characteristics (XRD) of a B₄C (B/C=4) material manufactured in examples according to an embodiment of the disclosure.

FIG. 5B illustrates crystal characteristics (XRD) of a C/B₄C (B/C=1.2) material manufactured in examples according to an embodiment of the disclosure.

FIG. 5C illustrates crystal characteristics (XRD) of a C/B₄C (B/C=0.6) composite material manufactured in examples according to an embodiment of the disclosure.

FIG. 6 illustrates a change in Vicker's hardness of a C/B₄C composite material according to a B/C ratio, according to an embodiment of the disclosure.

FIG. 7 illustrates an example of a process of a method of reproducing a composite material component for a semiconductor manufacturing apparatus according to the disclosure (e.g., a method of reproducing a focus ring) according to an embodiment of the disclosure.

FIG. 8 illustrates an example of a process of a method of reproducing a composite material component for a semiconductor manufacturing apparatus according to the disclosure (e.g., a method of reproducing a focus ring) according to another embodiment of the disclosure.

### BEST MODE FOR CARRYING OUT THE INVENTION

Hereinafter, embodiments of the present disclosure will be described in detail with reference to the accompanying drawings. When it is determined detailed description related to a related known function or configuration they may make the purpose of the present disclosure unnecessarily ambiguous in describing the present disclosure, the detailed description will be omitted here. In addition, terminologies used herein are defined to appropriately describe the embodiments and thus may be changed depending on a user, the intent of an operator, or a custom of a field to which the present disclosure pertains. Accordingly, the terminologies must be defined based on the following overall description of the present specification. In the drawings, like reference numerals are used for like elements.

In the whole specification, when a member is positioned “on” another member, this not only includes a case that the any member is brought into contact with the other member, but also includes a case that another member exists between two members.

It will be understood that when a certain part “includes” a certain component, the part does not exclude another component but may further include another component.

Hereinafter, an edge ring for a semiconductor manufacturing apparatus and a method of manufacturing the same of the disclosure will be described in detail with reference to embodiments and drawings. However, the disclosure is not limited to the embodiments and drawings.

According to an embodiment of the disclosure, an edge ring may include an upper layer 110 having high hardness; and a lower layer 120 positioned on a lower portion of the upper layer and having lower hardness than the upper layer 110.

According to an embodiment, the upper layer 110 may contain SiC or B₄C, and the lower layer 120 may contain a C-rich material, for example, C/SiC or C/B₄C. That is, since the C-rich material (e.g., C/SiC or C/B₄C) has high processability and lower hardness than the upper layer 110, a He leakage phenomenon due to the high hardness characteristic of the upper layer 110 may be solved. According to an embodiment of the disclosure, in the edge ring, a C/SiC or C/B₄C material, in which amorphous carbon is uniformly distributed within SiC (e.g., chemical vapor deposition (CVD) SiC) or B₄C (e.g., CVD B₄C), may be formed in the lower layer 120 that contacts with other components, and CVD SiC or CVD B₄C having plasma resistance may be formed in a plasma-exposed area, thereby improving adhesion with other components and the He leak phenomenon. That is, CVD SiC or CVD B₄C tends to have poor adhesion with other ceramic components due to high hardness, but the adhesion with other components may be improved by the C/SiC or C/B₄C material containing amorphous carbon having hardness similar to that of silicon.

According to an embodiment, the upper layer 110 has a plasma-exposed surface, and a thickness of the upper layer 110 may be at least 1 millimeter (mm) or more; 1.5 mm or more; 1 mm to 10 mm; or 1 mm to 5 mm. A maximum or minimum thickness value may be selected from the above-mentioned values. When the value is included within the above thickness range, the plasma resistance may be exhibited and the adhesion may be maintained when fixed to other ceramic components. According to an embodiment, the upper layer 110 may include a portion A, on which a semiconductor wafer substrate is seated, and for example, a thickness a of the portion A may be at least 1 mm or more; 1.5 mm or more; or 1 mm to 5 mm.

According to an embodiment, the lower layer 120 may be positioned to contact with an internal component (e.g., quartz) of a plasma etching apparatus, and may include a fastening portion B that is fixed and adhered to the internal component. A thickness of the lower layer 120 may be at least 0.2 mm or more; 0.3 mm or more; 0.5 mm or more; 0.2 mm to 10 mm; or 0.2 mm to 2 mm. The thickness may correspond to a maximum or minimum thickness value from the above-mentioned values. When the value is included within the above thickness range, the plasma resistance may be exhibited and the adhesion may be maintained when fixed to other ceramic components.

According to an embodiment, the lower layer 120 may be a lower surface having a contact surface with another component (e.g., quartz) and may include the fastening portion B that is fixed and adhered to the other component, and for example, a thickness b of the portion may be at least 0.2 mm or more; 0.3 mm or more; or 0.2 mm to 2 mm.

According to an embodiment, the lower layer 120 may contain a C/SiC material, and the physical properties may be adjusted by a ratio of raw materials during C/SiC deposition. For example, a raw material ratio of Si:C during the deposition of the C/SiC composite layer 110 may be 1:1.4 to 1:1.6; 1:1.4 to 1:(less than) 1.6; 1:1.41 to 1:1.59, 1:1.44 to 1:1.57; 1:1.49 to 1:1.57; or 1:1.5 to 1:1.55. By controlling the raw material ratio, damage to semiconductor components due to collision or impact in a semiconductor process such as a plasma environment may be prevented, and an appropriate Vicker's hardness may be secured so that the edge ring has adhesion with other components.

According to an embodiment, the lower layer 120 may contain a C/B₄C material, and the physical properties may be adjusted by a ratio of raw materials during C/B₄C deposition. For example, a raw material ratio of B:C in the C/B₄C material may be more than 0:1 to less than 4:1; 0.1:1 to less than 4:1; 0.2:1 to 3:1; 0.3:1 to 2:1; or 0.5:1 to 1.5:1. By controlling the raw material ratio, damage to semiconductor components due to collision or impact in a semiconductor process such as a plasma environment may be prevented, and an appropriate Vicker's hardness may be secured so that the edge ring has adhesion with other components.

According to an embodiment, the Vicker's hardness of the lower layer 120 (C/SiC or C/B₄C) may be 1000 kg_{f}/mm² to 2000 kg_{f}/mm², and desirably may be similar to or lower than that of silicon.

When the Vicker's hardness of the lower layer is less than 1000 kg_{f}/mm², handling may be difficult due to impact or chipping caused by impact due to low hardness. When the hardness of the lower layer exceeds 2000 kg_{f}/mm², the adhesion with other components may be low due to high hardness, which may cause a problem of He gas leakage.

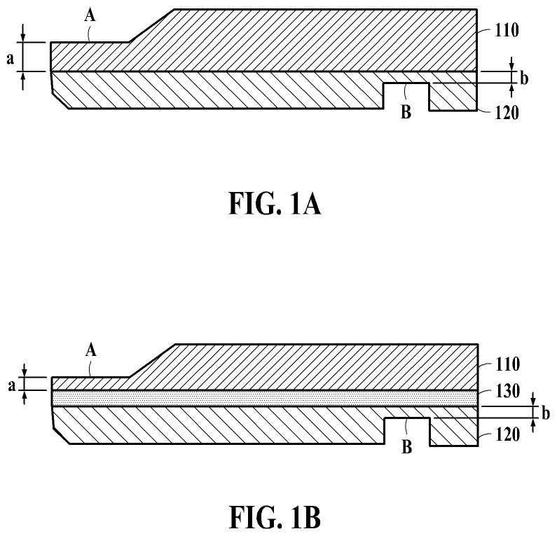

According to an embodiment, the lower layer 120 and the upper layer 110 are formed by deposition, and a bonding layer-free (a non-adhesive layer) (FIG. 1A) may be formed between the lower layer 120 and the upper layer 110. A carbon source from a predetermined thickness or more during the formation of the upper layer 110 (e.g., CVD SiC or CVD B₄C) may be increased to form a dense C/SiC composite layer or C/B₄C with improved adhesion to other ceramic components by a continuous CVD deposition method.

According to an embodiment, the edge ring may be deposited by a CVD method. When the lower layer 120 is formed of C/SiC, the deposition may be performed while continuously changing the raw material ratio of Si to C, and when the lower layer 120 is formed of C/B₄C, the deposition may be performed while continuously changing the raw material ratio of B to C.

According to an embodiment, when forming the upper layer 110, the upper layer 110 may be formed by CVD, reaction sintering, or sintering. According to an embodiment, when forming the lower layer 120, the lower layer 120 may be deposited on the upper layer 110.

According to an embodiment, the upper layer 110 may be formed on a substrate, and the substrate may be graphite or the like, but is not limited thereto. According to an embodiment, the upper layer 110 may be formed by CVD, reaction sintering, or sintering, and may be formed at a temperature of, for example, 1100° C. to 1700° C.; or, to control a growth rate and a raw material ratio, 1200° C. to 1450° C. The conditions described above may be process conditions applied to the CVD, the reaction sintering, or the sintering. For example, the formation may be performed at a temperature of 1100° C. to 1700° C.; or to control a growth rate and a raw material ratio, 1200° C. to 1450° C. and a pressure of 700 torr to 760 torr. The conditions described above may be process conditions applied to the CVD, the reaction sintering, or the sintering. According to an embodiment, according to the temperature, the pressure, or both, the raw material ratio of Si:C or the raw material ratio of B:C applied during the deposition of each layer may be selected within the range of the raw material ratio of Si:C or the raw material ratio of B:C mentioned above in order to secure the physical properties of the edge ring, which is a component for a semiconductor manufacturing apparatus of the disclosure.

According to an embodiment, when forming the lower layer 120, the lower layer 120 may be deposited while continuously changing the raw material ratio of B:C or Si:C.

According to an embodiment, the lower layer 120 and the upper layer 110 may be bonded to each other. For example, the bonding may be performed using at least one or more of heat, pressure, and an adhesive. According to an embodiment, when forming the lower layer 120, the upper layer 110 and the lower layer 120 may be bonded. According to an embodiment, the bonding of the upper layer 110 and the lower layer 120 may be performed using at least one or more of an adhesive, heat, and pressure, or a combination thereof. According to an embodiment, an edge ring including an adhesive layer 130 between the upper layer 110 and the lower layer 120 may be formed as shown in FIG. 1B. For example, each of the upper layer 110 and the lower layer 120 may be formed on a substrate and bonded after applying an adhesive onto the upper layer 110, the lower layer 120, or a surface thereof. Heat, pressure, or both may be applied during bonding. The adhesive may be applied without limitation as long as it is applicable to ceramic bonding.

According to an embodiment, each of the upper layer 110 and the lower layer 120 may be formed on a substrate, and the upper layer 110 and the lower layer 120 may be disposed to be in contact with each other, and then bonded by applying the heat, pressure, or both.

According to an embodiment, the upper layer 110 and the lower layer 120 may be formed and processed in a component form (edge ring). For example, the edge ring may be processed so that the lower layer 120 (a C/B₄C layer or a C/SiC layer), which is in close contact with other components, is positioned, and the upper layer 110 (a SiC layer or a B₄C layer), to which plasma is exposed and on which a semiconductor wafer is seated to contact therewith, is positioned. The specific shape of the edge ring may be formed using shapes and processing methods known in the technical field of the disclosure, may be appropriately selected as long as it does not depart from the purpose and scope of the disclosure, and is thus not specifically mentioned in this specification.

### Example 1

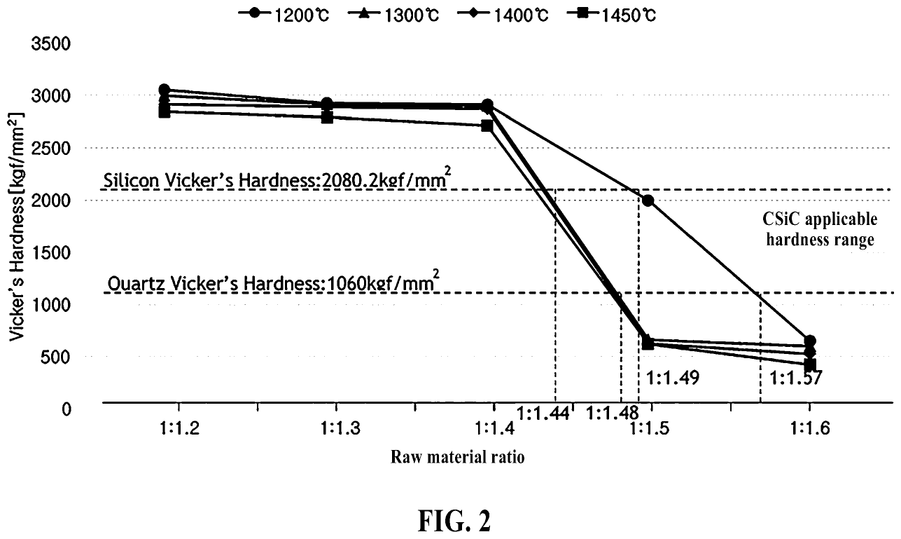

C/SiC materials were manufactured according to the Si/C ratios in Table 2 using the CVD method. A X-ray diffraction (XRD) and a Vicker's hardness of the C/SiC materials were measured. The results thereof are shown in Table 1 and FIG. 2.

The Vicker's hardness of the C/SiC material according to the raw material ratio of Si:C and the process temperature of the composite material manufactured in Example 1 was measured and shown in Table 1 and FIG. 2.

TABLE 1

| | Vicker's hardness (kg_{f}/mm²) | | | | |
|---|---|---|---|---|---|
| | Process | | | | |
| | temperature | | | | |
| | [° C.] | 1200° C. | 1300° C. | 1400° C. | 1450° C. |
| Si:C ratio | 1:1.2 | 3054.8 | 2998.3 | 2917.2 | 2845.8 |
| of sup- | 1:1.3 | 2926.6 | 2915.3 | 2891.5 | 2795.4 |
| plied raw | 1:1.4 | 2912.8 | 2901.1 | 2872.8 | 2716.2 |
| materials | 1:1.5 | 1998.6 | 663.2 | 625.8 | 623.1 |
| | 1:1.6 | 653.2 | 602.5 | 528.9 | 425.5 |

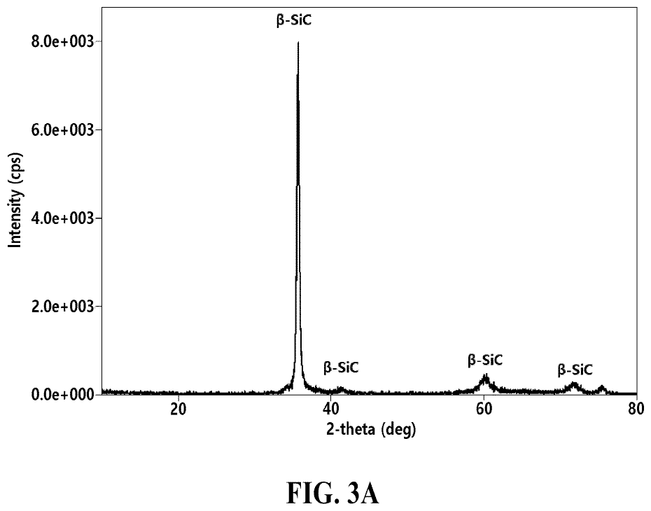

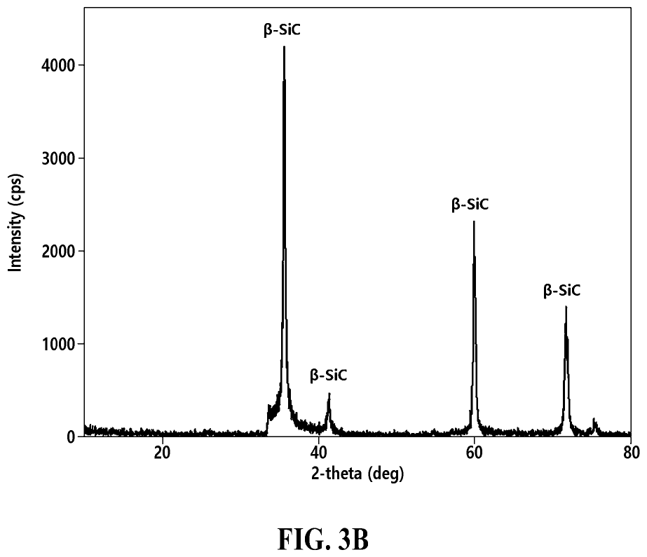

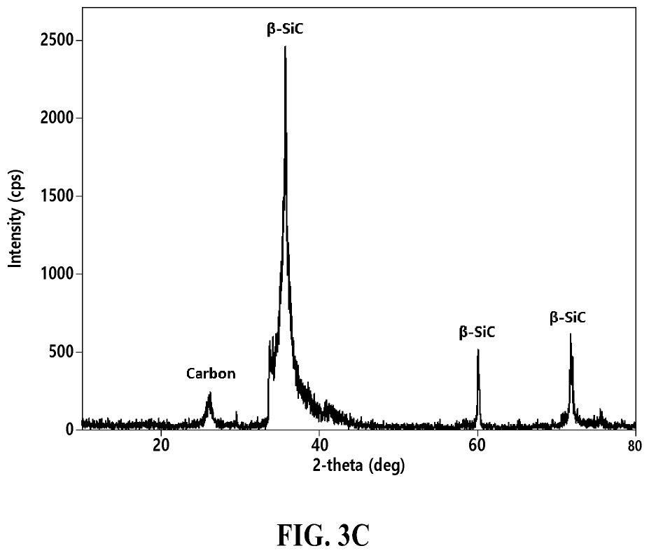

The XRD of the CSIC material according to the raw material ratio of Si:C and the process temperature of the composite material manufactured in Example 1 was measured and shown in FIGS. 3A to 3C, and XRD peak values were shown in Tables 2 and 3.

According to Table 1 and FIGS. 2 and 3A to 3C, it may be confirmed that, when the Si:C raw material ratio is 1:1.5 or more, crystalline SiC and crystalline carbon are formed, resulting in low hardness. The Si:C raw material ratio is in the range of 1:1.44 to 1.49, which is similar to the Vicker's hardness of silicon and quartz, and excellent adhesion to silicon and quartz materials may be provided. That is, as shown in Table 1 and FIG. 2, it may be confirmed that the hardness of the C/SiC material changes depending on the Si:C ratio, the Vicker's hardness of silicon is 2080 kg_{f}/mm², the Si:C raw material ratio is 1:1.44 to 1.48 at a process temperature of 1300° C. to 1400° C., the Si:C raw material ratio is 1:1.49 to 1.57 at 1200° C. to 1300° C., and the Si:C raw material ratio is desirably 1:1.5 to 1.55, which may be advantageous in securing adhesion with other components. This may correspond to a C/SiC material that may achieve hardness applicable to the edge ring.

Table 2 shows SiC (111) peak intensity values by measuring the XRD of the CSiC material according to the raw material ratio of Si:C and the process temperature of the composite material manufactured in Example 1.

TABLE 2

| | Diffraction intensity of SiC (111) (cps) | | | | |
|---|---|---|---|---|---|
| | Process | | | | |
| | temperature | | | | |
| | [° C.] | 1200° C. | 1300° C. | 1400° C. | 1450° C. |
| Si:C ratio | 1:1.0 | 25436 | 10536 | 12801 | 11256 |
| of sup- | 1:1.2 | 8981 | 5351 | 3108 | 2724 |
| plied raw | 1:1.3 | 5613 | 4653 | 2692 | 2405 |
| materials | 1:1.4 | 4512 | 3185 | 2056 | 1935 |
| | 1:1.5 | 2759 | 2082 | 512 | 521 |
| | 1:1.6 | 2105 | 1824 | 298 | 317 |

Table 3 shows peak intensity values of carbon by measuring the XRD of the CSIC material according to the raw material ratio of Si:C and the process temperature of the composite material manufactured in Example 1.

TABLE 3

| | Diffraction intensity of Carbon (cps) | | | | |
|---|---|---|---|---|---|
| | Process | | | | |
| | temperature | | | | |
| | [° C.] | 1200° C. | 1300° C. | 1400° C. | 1450° C. |
| Si:C ratio | 1:1.0 | 0 | 0 | 0 | 0 |
| of sup- | 1:1.2 | 0 | 0 | 0 | 0 |
| plied raw | 1:1.3 | 0 | 0 | 0 | 0 |
| materials | 1:1.4 | 0 | 0 | 0 | 0 |
| | 1:1.5 | 0 | 38 | 51 | 42 |
| | 1:1.6 | 0 | 105 | 112 | 106 |

Tables 2 and 3 show SiC (111) diffraction intensity of the C/SiC material and diffraction intensity of the carbon peak of the CSIC material under each process condition. It may be confirmed that, when the Si:C raw material ratio is 1:1.5 or more and the process temperature is 1300° C. or higher, the SiC (111) diffraction intensity decreases, and the carbon diffraction intensity increases due to the increase in crystalline carbon.

FIG. 3A shows an XRD pattern of a CSIC material having a Si:C raw material ratio of 1:1 to 1.1 (deposition temperature: 1300° C.), FIG. 3B shows an XRD pattern of a CSiC material having a Si:C raw material ratio of 1:1.2 to 1.4 (deposition temperature: 1300° C.), and FIG. 3C shows an XRD pattern of a CSiC material having a Si:C raw material ratio of 1:1.5 to 1.6 (deposition temperature: 1300° C.). In FIG. 3C, it may be confirmed that a peak of crystalline carbon grows as the carbon raw material ratio increases.

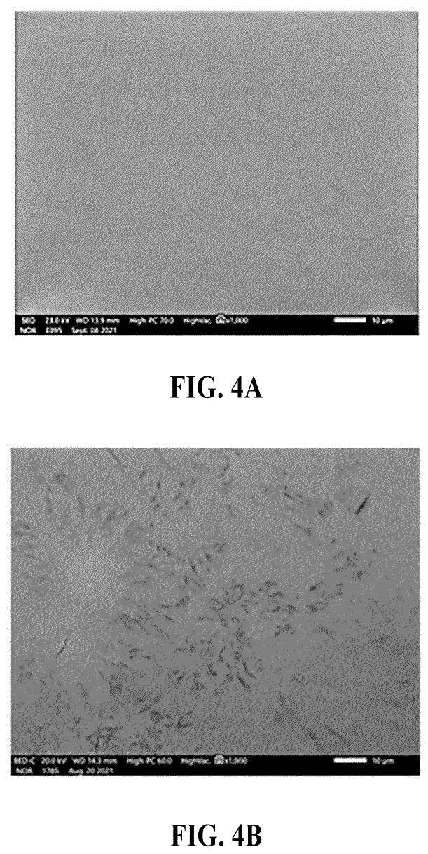

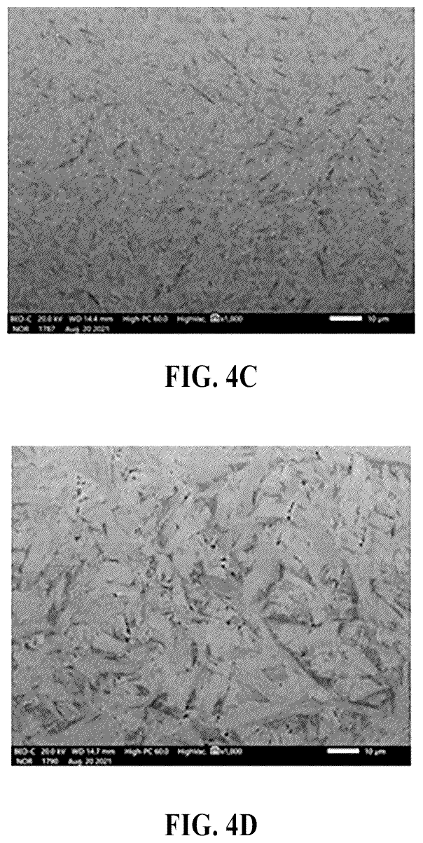

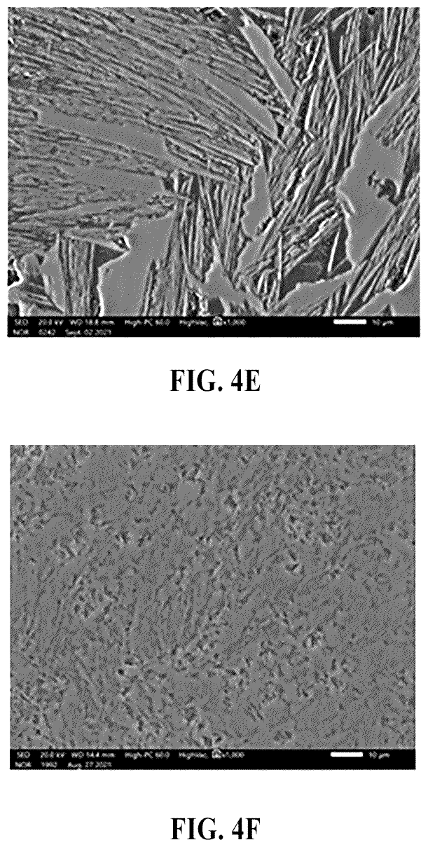

FIGS. 4A, 4B, 4C, 4D, 4E, and 4F show SEM images of a C/SiC material layer according to the Si:C raw material ratio of the composite material manufactured in Example 1. FIG. 4A shows a Si:C raw material ratio of 1:1.1, FIG. 4B shows a Si:C raw material ratio of 1:1.2, FIG. 4C shows a Si:C raw material ratio of 1:1.3, FIG. 4D shows a Si:C raw material ratio of 1:1.4, FIG. 4E shows a Si:C raw material ratio of 1:1.5, and FIG. 4F shows a Si:C raw material ratio of 1:1.6. In FIGS. 4A, 4B, 4C, 4D, 4E, and 4F, it may be seen that a microstructure of a surface of the C/SiC material changes and pores are formed as the Si:C raw material increases.

### Example 2

B4C and SiC materials were manufactured by the CVD method. A plasma etching rate according to the material was evaluated and shown in Table 4.

TABLE 4

| | Etching Rate [μm/hr.] | | | |
|---|---|---|---|---|
| Sample | 1 | 2 | 3 | Avg. |
| CVD-B4C | 3.83 | 3.69 | 3.61 | 3.71 |
| CVD-SiC | 5.7 | 5.7 | 5.71 | 5.70 |
| Silicon | 11.98 | 12.06 | 12.23 | 12.09 |
| Etching improvement | 68.3% | 69.5% | 70.1% | 69.3% |
| rate compared to Si | | | | |
| Etching improvement | 32.8% | 35.3% | 36.7% | 35.0% |
| rate compared to SiC | | | | |

* An etching improvement rate in Table 4 is a value related to CVD-B₄C.

As shown in Table 4, it may be confirmed that the CVD B₄C material has plasma corrosion resistance that is about 35% better than that of CVD SiC, and the disclosure may provide an edge ring using the CVD B₄C material having excellent plasma corrosion resistance.

### Example 3

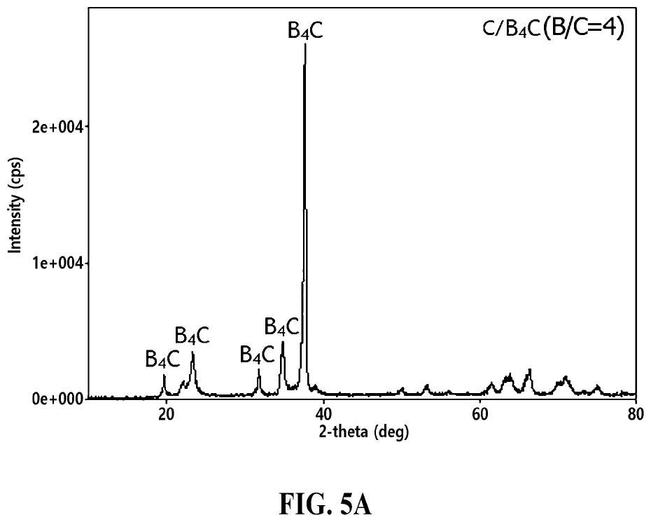

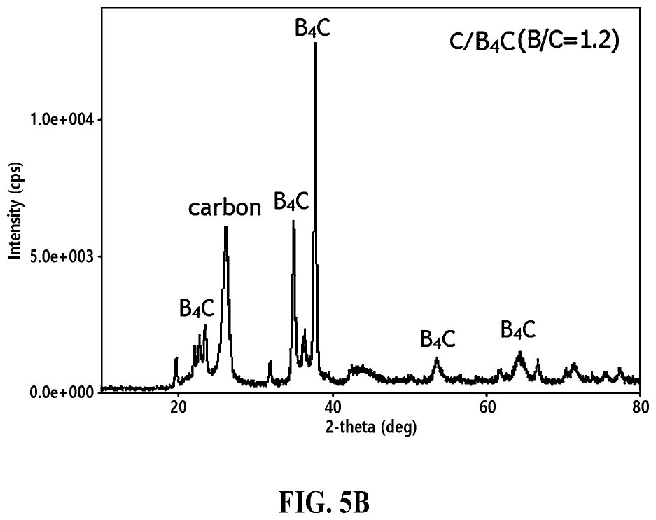

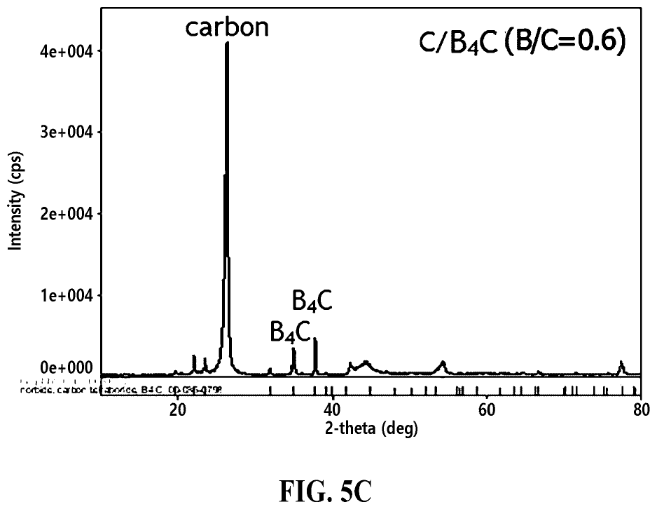

A C/B₄C material according to the B/C ratio in Table 2 was manufactured by the CVD method. An XRD and Vicker's hardness of the C/B₄C material were measured. The results thereof are shown in Table 5 and FIG. 5.

TABLE 5

| | Vicker's Hardness (kg_{f}/mm²) | | | | | |
|---|---|---|---|---|---|---|
| B/C ratio | 1 | 2 | 3 | 4 | 5 | average |
| B/C = 4.9 | 3186 | 3278 | 3055 | 3115 | 3098 | 3146.4 |
| B/C = 4 | 3106 | 3115 | 3078 | 3173 | 3054 | 3105.2 |
| B/C = 2 | 3178 | 3003 | 3055 | 3072 | 3053 | 3072.2 |
| B/C = 1.9 | 3086 | 3098 | 3042 | 3098 | 3055 | 3075.8 |
| B/C = 1.7 | 3026 | 3070 | 2931 | 3057 | 3147 | 3046.2 |
| B/C = 1.2 | 1835 | 1972 | 1854 | 1736 | 1865 | 1852.4 |
| B/C = 1 | 1038 | 990 | 923 | 959 | 944 | 970.8 |
| B/C = 0.6 | 475 | 432 | 443 | 461 | 472 | 456.6 |

As shown in FIGS. 5A to 5C, for the CVD B₄C material, carbon and B₄C peaks may be confirmed in the XRD pattern. It may be seen that the intensity of the carbon peak increases as the B/C ratio decreases.

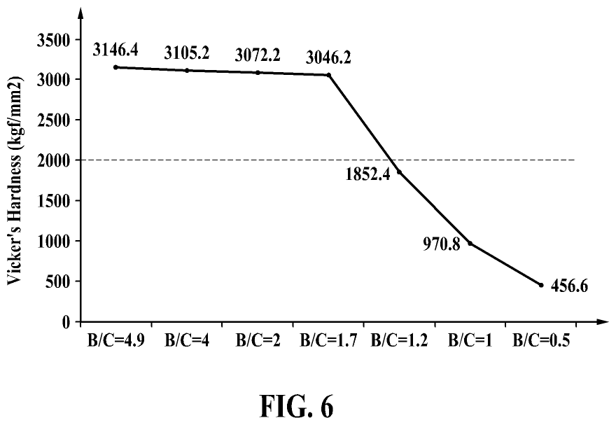

As shown in FIG. 6 and Table 5, the hardness of the CVD B₄C material tends to decrease as the B/C ratio decreases. Here, the Vicker's hardness of silicon is about 2080 kg_{f}/mm², and based on this, when the B/C ratio is 1.2 or less, it has lower hardness than silicon, which may ensure adhesion to other components.

When the Vicker's hardness is 500 kg_{f}/mm² or less, the material may be difficult to handle due to the problem of chips being generated during impact or collision. Accordingly, the hardness of 1000 kg_{f}/mm² or more is required, and this may be achieved at a B/C ratio of CB₄C of 1 to 1.2.

In the disclosure, B₄C having a B/C ratio of 4 and silicon or a C-rich boron carbide (CBC) material having a B/C ratio of 1 to 1.2 may be bonded through a physical or chemical bonding method, and such bonding material may be utilized as a material for an edge ring. That is, the silicon or C-rich boron carbide portion of the edge ring may be configured as a portion that comes into contact with other ceramic components, and B₄C may be configured as a portion that is exposed to the plasma. The edge ring having such a configuration may have improved plasma durability and adhesion to other components.

The disclosure may provide an edge ring, in which a C/B₄C or C/SiC material having a high C component and hardness similar to silicon is formed in a portion requiring adhesion with other ceramic components, thereby solving the low adhesion due to the high hardness of the CVD SiC and He gas leakage in the related art while securing the plasma resistance by the CVD SiC.

A method of reproducing a composite material component for a semiconductor manufacturing apparatus according to an embodiment is a method of reproducing an edge ring, and the method includes forming a lower layer on a lower surface of an upper layer of a focus ring; and processing a shape of the focus ring to contain the lower layer.

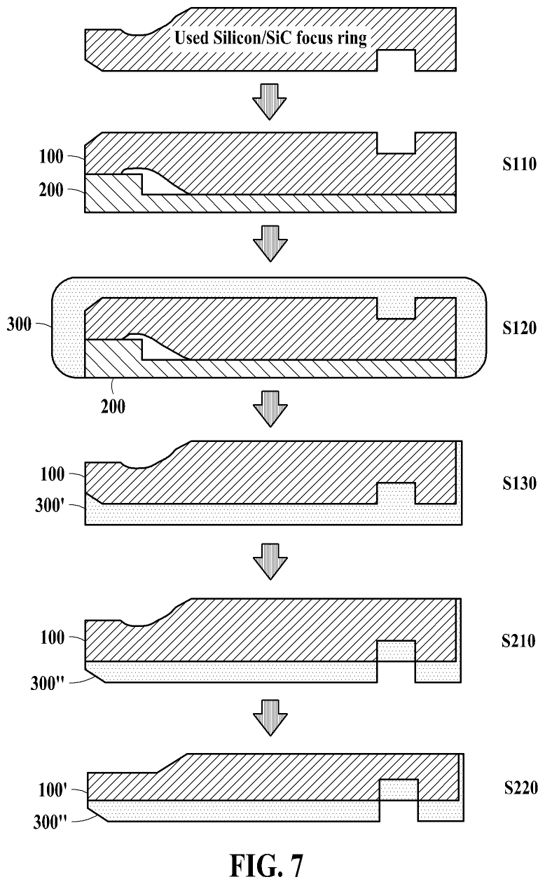

FIG. 7 illustrates an example of a process of a method of reproducing a composite material component for a semiconductor manufacturing apparatus of the disclosure (e.g., a method of reproducing a focus ring) according to an embodiment of the disclosure.

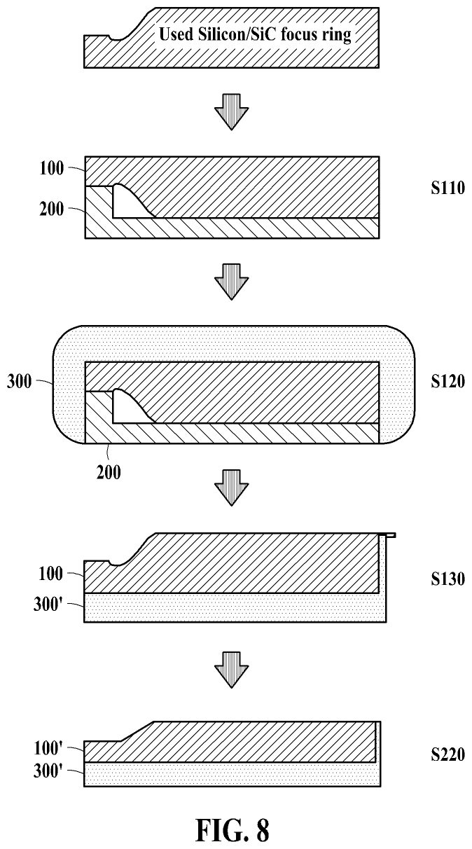

FIG. 8 illustrates an example of a process of a method of reproducing a composite material component for a semiconductor manufacturing apparatus of the disclosure (e.g., a method of reproducing a focus ring) according to another embodiment of the disclosure.

Referring to FIGS. 7 and 8, FIGS. 7 and 8 illustrate a process of a reproduction method according to a shape of a used focus ring 100, and in FIG. 7, the method may include operation S110 of attaching a jig 200 for coating on an upper surface, operation S120 of depositing a C/SiC coating layer 300 to surround a lower surface and a side surface; operation S130 of removing the jig 200; operation S210 of processing the C/SiC coating layer 300; and operation S220 of processing the upper surface. In operation S130 of removing the jig 200, the C/SiC coating layer 300 may be processed.

In FIG. 8, the method may include operation S110 of attaching the jig 200 for coating on the upper surface, operation S120 of depositing the C/SiC coating layer 300 to surround the lower surface and the side surface; operation S130 of removing the jig 200; and operation S220 of processing the upper surface.

Operation S220 of processing the upper surface may remove a silicon or SiC layer damaged by etching or the like from the used focus ring.

According to an embodiment, the upper layer may contain SiC or B₄C, and the lower layer may contain C/SiC or C/B₄C.

According to an embodiment, the operation of forming the lower layer may include forming the lower layer on at least one of a lower surface, an upper surface, or a side surface of the focus ring, and the upper surface may be a plasma-exposed surface.

According to an embodiment, the operation of processing of the shape of the focus ring may include processing the shape so that the C/SiC coating layer becomes a lower surface of the focus ring.

According to an embodiment, the operation of processing of the shape of the focus ring may include processing the shape into a focus ring including an upper surface that has an area designed for wafer seating and is a plasma-exposed surface; and a lower surface.

According to an embodiment, the operation of forming of a lower surface on at least one surface of the focus ring may include attaching a jig for coating on the at least one surface of the focus ring, the attaching of the jig for coating may include attaching the jig for coating on an upper surface of the focus ring and may include depositing the lower surface on the at least one surface of the focus ring, to which the jig is attached, and the operation of depositing of the lower layer may be depositing the lower layer on at least one surface except for the surface, on which the jig for coating is formed, and may include removing the jig for coating after the depositing of the lower layer.

According to an embodiment, the method may include processing a shape of a lower surface and/or an upper surface of the focus ring.

While a few example embodiments have been shown and described with reference to the accompanying drawings, it will be apparent to those skilled in the art that various modifications and variations can be made from the foregoing descriptions. For example, adequate effects may be achieved even if the foregoing processes and methods are carried out in different order than described above, and/or the aforementioned elements are combined or coupled in different forms and modes than as described above or be substituted or switched with other components or equivalents. Thus, other implementations, alternative embodiments and equivalents to the claimed subject matter are construed as being within the appended claims.

1. An edge ring comprising:
an upper layer having high hardness; and
a lower layer positioned on a lower portion of the upper layer and having lower hardness than the upper layer,
wherein the lower layer is positioned to be in contact with an internal component of a plasma etching apparatus.

2. The edge ring of claim 1, wherein the upper layer is formed of SiC or B₄C.

3. The edge ring of claim 1, wherein the upper layer has a thickness of 1 millimeter (mm) or more.

4. The edge ring of claim 1, wherein the lower layer is formed of C/SiC or C/B₄C.

5. The edge ring of claim 4, wherein
the lower layer is formed of a C/SiC material, and
an atomic ratio of Si:C is 1:1.4 to 1:1.6.

6. The edge ring of claim 4, wherein
the lower layer is formed of a C/B₄C material, and
an atomic ratio of B:C is more than 0:1 to less than 4:1.

7. The edge ring of claim 1, wherein the lower layer has a Vicker's hardness of 1000 kg_{f}/mm² to 2000 kg_{f}/mm².

8. The edge ring of claim 1, wherein the lower layer has a thickness of 0.2 mm or more.

9. The edge ring of claim 1, wherein the lower layer is deposited and formed on the upper layer.

10. The edge ring of claim 9, wherein
the edge ring is deposited using a chemical vapor deposition (CVD) method,
when the lower layer is formed of C/SiC, deposition is performed while continuously changing a raw material ratio of Si to C, and
when the lower layer is formed of C/B₄C, deposition is performed while continuously changing a raw material ratio of B to C.

11. A method of manufacturing an edge ring, the method comprising:
forming a high-hardness upper layer;
forming a lower layer having lower hardness than the upper layer; and
processing in a component form.

12. The method of claim 11, wherein, when forming the upper layer, the upper layer is formed by chemical vapor deposition (CVD), reaction sintering, or sintering.

13. The method of claim 11, wherein, when forming the lower layer, the lower layer is deposited on the upper layer.

14. The method of claim 13, wherein, when forming the lower layer, the lower layer is deposited while continuously changing a raw material ratio of B:C or Si:C.

15. A method of reproducing a composite material component for a semiconductor manufacturing apparatus that is a method of reproducing the edge ring of claim 2, the method comprising:
forming a lower layer on a lower surface of an upper layer of a focus ring; and
processing a shape of the focus ring to contain the lower layer.

16. The method of claim 15, wherein
the upper layer comprises SiC or B₄C, and
the lower layer comprises C/SiC or C/B₄C.

17. The method of claim 15, wherein
the forming of the lower layer comprises forming the lower layer on at least one of a lower surface, an upper surface, or a side surface of the focus ring, and
the upper surface is a plasma-exposed surface.

18. The method of claim 15, wherein the processing of the shape of the focus ring comprises processing the shape so that a C/SiC coating layer becomes a lower surface of the focus ring.

19. The method of claim 15, wherein the processing of the shape of the focus ring comprises processing the shape into a focus ring comprising an upper surface that has an area designed for wafer seating and is a plasma-exposed surface; and a lower surface.

20. The method of claim 15, wherein
the forming of a lower surface on at least one surface of the focus ring comprises attaching a jig for coating on the at least one surface of the focus ring,
the attaching of the jig for coating is attaching the jig for coating on an upper surface of the focus ring and comprises depositing the lower surface on the at least one surface of the focus ring, to which the jig is attached, and
the depositing of the lower layer is depositing the lower layer on at least one surface except for the surface, on which the jig for coating is formed, and comprises removing the jig for coating after the depositing of the lower layer.

21. The method of claim 15, comprising:
processing a shape of a lower surface and/or an upper surface of the focus ring.
